(19) United States
(12) Patent Application Publication
(10) Pub. No.: US 2026/0058438 A1
(43) Pub. Date: Feb. 26, 2026

(54) SEMICONDUCTOR LIGHT-EMITTING DEVICE

(71) Applicant: HAMAMATSU PHOTONICS K.K., Hamamatsu-shi (JP)

(72) Inventors: Tadataka EDAMURA, Shizuoka (JP); Yoshitaka KUROSAKA, Shizuoka (JP); Yutaka TAKAGI, Shizuoka (JP); Akio ITO, Shizuoka (JP); Masahiro HITAKA, Shizuoka (JP); Kazuyoshi HIROSE, Shizuoka (JP); Takahiro SUGIYAMA, Shizuoka (JP)

(73) Assignee: HAMAMATSU PHOTONICS K.K., Hamamatsu-shi (JP)

(21) Appl. No.: 19/304,393

(22) Filed: Aug. 19, 2025

(30) Foreign Application Priority Data
Aug. 22, 2024 (JP) 2024-141003

(51) Int. Cl. H01S 5/183; H01S 5/024; H01S 5/40; H01S 5/42

(52) U.S. Cl. CPC H01S 5/18302; H01S 5/02415; H01S 5/18305; H01S 5/4018; H01S 5/423

(57) ABSTRACT

A semiconductor light-emitting device includes a plurality of unit light-emitting elements, in which the unit light-emitting elements each include a stacked structure including a substrate, an active layer, a phase modulation layer including a base region having a first refractive index and a plurality of different refractive index regions two-dimensionally distributed in the base region with a second refractive index, a plurality of light emission regions configured to emit laser light generated by mode formation of the light incident on the phase modulation layer from the active layer to outside, and a first electrode and a second electrode having polarities different from each other, the stacked structures in the plurality of unit light-emitting elements are independent of each other, and the plurality of unit light-emitting elements is two-dimensionally arranged in a state of being separated from each other to constitute a light-emitting element array.

### TECHNICAL FIELD

The present disclosure relates to a semiconductor light-emitting device.

### BACKGROUND

As a technique related to this type of field, for example, there is a semiconductor light-emitting element described in “M. Yoshida et al., “High-brightness scalable continuous-wave single-mode photonic crystal laser.” Nature 618, 727-732 (2023)” which is a non-patent document. The semiconductor light-emitting element according to this non-patent document is a light-emitting element called a photonic crystal surface emitting laser (PCSEL). This semiconductor light-emitting element is configured by stacking a photonic crystal layer including an active layer and a phase modulation layer on a substrate.

### SUMMARY

In the semiconductor light-emitting element as described above, an increase in output has been a problem from the viewpoint of application expansion. One approach for increasing the output of the semiconductor light-emitting element is, for example, increasing the area of the device. However, it is considered that there is a limit to increase the output of the semiconductor light-emitting element due to an increase in the area of the element due to the influence of warpage of the substrate and the like caused by heat generation during driving. In addition, even if the size of the light emission region is simply increased in accordance with the size of the element, a problem of mode competition, a problem of disturbance of a beam pattern due to non-uniformity of temperature distribution in the light emission region, and the like may occur.

Examples of a method for suppressing mode competition and disturbance of a beam pattern while increasing the area of an element include arraying light emission regions of the element. For example, the semiconductor light-emitting element disclosed in Japanese Patent Application Laid-Open No. 2023-131320 is a light-emitting element called an iPMSEL (integrable phase modulating surface emitting lasers) capable of outputting a two-dimensional beam pattern. In this semiconductor light-emitting element, a plurality of light emission regions separated from each other is arranged on a single substrate. When the arrangement of such a plurality of light emission regions is considered, the mode competition and the disturbance of the beam pattern can be suppressed. However, warpage of the substrate due to heat generation during driving may remain as a problem.

Another approach for increasing the output of the semiconductor light-emitting element includes arraying a plurality of semiconductor light-emitting elements. When the arrangement of such a plurality of semiconductor light-emitting elements is considered, elements having a size that can solve problems such as mode competition can be arranged. However, if the size of the element is too small, a Fabry-Perot resonance mode between end surfaces of the element becomes dominant rather than the diffraction effect in the photonic crystal layer, and it is considered that it becomes difficult to extract laser light in a direction perpendicular to the plane. In addition, the difficulty and cost of manufacturing relating to alignment of the plurality of semiconductor light-emitting elements and conduction between the semiconductor light-emitting elements may increase, leading to a decrease in yield.

The present disclosure has been made to solve the above problems, and an object thereof is to provide a semiconductor light-emitting device capable of extracting laser light having desired characteristics with high output by optimizing the size of an element.

The gist of the present disclosure is as follows.
[1] A semiconductor light-emitting device including a plurality of unit light-emitting elements, in which the unit light-emitting elements each include a stacked structure including a substrate, an active layer configured to generate light by supplying a drive current, a phase modulation layer including a base region having a first refractive index and a plurality of different refractive index regions two-dimensionally distributed in the base region with a second refractive index different from the first refractive index, a plurality of light emission regions configured to emit laser light generated by mode formation of the light incident on the phase modulation layer from the active layer to outside, and a first electrode on a side of the light emission regions and a second electrode on a side opposite to the light emission regions, the first electrode and the second electrode having polarities different from each other, the stacked structures in the plurality of unit light-emitting elements are independent from each other, and the plurality of unit light-emitting elements is two-dimensionally arranged in a state of being separated from each other to constitute a light-emitting element array.

In this semiconductor light-emitting device, stacked structures of unit light-emitting elements having a plurality of light emission regions are made independent from each other, and the plurality of unit light-emitting elements is two-dimensionally arranged in a state of being isolated from each other to constitute a light-emitting element array. In this semiconductor light-emitting device, by including the plurality of light emission regions in each unit light-emitting element in which the stacked structures are independent from each other, the element size of each unit light-emitting element can be sufficiently secured, and the influence of a Fabry-Perot resonance mode between the end surfaces of the elements can be reduced. In addition, by two-dimensionally arranging the unit light-emitting elements including the plurality of light emission regions, it is possible to extract the laser light from each light emission region while eliminating an influence such as warpage of the substrate due to heat generation during driving and a problem of mode competition. Therefore, in this semiconductor light-emitting device, laser light having desired characteristics can be extracted with high output.
[2] The semiconductor light-emitting device according to [1], in which the unit light-emitting elements each include a thermoconductive outermost layer thermally coupled to the active layer and the phase modulation layer. In this case, heat during driving in the unit light-emitting element can be efficiently released to the outside through the thermoconductive outermost layer. Thus, the output of the laser light is stabilized.

[3] The semiconductor light-emitting device according to [2], further including a cooling unit thermally coupled in common to the thermoconductive outermost layer of each of the plurality of unit light-emitting elements. Thus, even when a large number of unit light-emitting elements are two-dimensionally arranged, each unit light-emitting element can be efficiently cooled. In addition, by making the cooling unit common to the plurality of unit light-emitting elements, it is possible to avoid complication of the configuration of the light-emitting element array.
[4] The semiconductor light-emitting device according to [3], in which the cooling unit includes a positioning portion corresponding to each of the plurality of unit light-emitting elements. Thus, it is possible to improve the positional accuracy of each unit light-emitting element when a large number of unit light-emitting elements are two-dimensionally arranged.
[5] The semiconductor light-emitting device according to [4], in which the positioning portion is a wall portion extending in a stacking direction of the stacked structure, and an insulating film is provided on a surface of the wall portion on a side of the stacked structure. In this case, the unit light-emitting element can be easily positioned by abutting the stacked structure against the wall portion. In addition, by providing the insulating film on the surface of the wall portion on the stacked structure side, the occurrence of a short circuit due to the wall portion can be prevented.
[6] The semiconductor light-emitting device according to any one of [1] to [5], in which the unit light-emitting elements each include an electroconductive outermost layer electrically connected to the second electrode. In this case, the unit light-emitting elements can be easily electrically connected to each other via the electroconductive outermost layer.
[7] The semiconductor light-emitting device according to [6], in which the electroconductive outermost layer has an overhanging portion overhanging in a direction intersecting a stacking direction in the stacked structure. By providing the overhanging portion in the electroconductive outermost layer, it is easy to electrically connect the unit light-emitting elements adjacent to each other.
[8] The semiconductor light-emitting device according to [7], in which the unit light-emitting elements adjacent to each other are electrically connected in series by connecting the overhanging portion of one of the unit light-emitting elements to the first electrode of another of the unit light-emitting elements. According to such a configuration, even when a large number of unit light-emitting elements are two-dimensionally arranged, the wiring can be simplified.
[9] The semiconductor light-emitting device according to [8], in which a current path including a current supply unit and a fuse element is formed for each of the unit light-emitting elements adjacent to each other. According to such a configuration, when the unit light-emitting elements adjacent to each other are sectionalized as one segment, the current supply unit is provided for each segment SG, so that variations in the output of the laser light between the segments can be suppressed. In addition, since the fuse element is provided for each segment, even when a failure occurs in one segment, it is possible to continue the output of the laser light from the other segment SG. At this time, it is possible to smoothly recover the output of the laser light by replacing the failed segment during driving of the non-failed segment. Note that the “unit light-emitting elements adjacent to each other” is not limited to an aspect in which a pair of unit light-emitting elements is adjacent to each other, and may include an aspect in which three or more unit light-emitting elements are adjacent to each other.
[10] The semiconductor light-emitting device according to [9], in which the current path for each of the unit light-emitting elements adjacent to each other is electrically connected to a common ground. According to such a configuration, even when a large number of unit light-emitting elements are two-dimensionally arranged, the wiring can be simplified.
[11] The semiconductor light-emitting device according to any one of [1] to [10], further including an illumination optical system configured to uniformize the laser light emitted from the light emission region. In this case, even when the laser light is emitted from any of the plurality of light emission regions, the same irradiation region at the designed irradiation position can be irradiated with the laser light. Therefore, the output of the semiconductor light-emitting device can be further increased, and the degree of freedom in driving the device can be increased.

### BRIEF DESCRIPTION OF THE DRAWINGS

FIG. 1 is a schematic cross-sectional view illustrating a configuration of a unit light-emitting element;

FIG. 2 is an enlarged plan view illustrating a part of a phase modulation layer;

FIG. 3 is a schematic plan view illustrating a configuration of a semiconductor light-emitting device;

FIG. 4 is a cross-sectional view taken along line IV-IV in FIG. 3;

FIG. 5 is a schematic view illustrating an example of an illumination optical system;

FIG. 6 is a schematic view illustrating another example of the illumination optical system;

FIG. 7 is a schematic view illustrating an example of a method for driving the semiconductor light-emitting device;

FIG. 8 is a schematic view illustrating another example of the method for driving the semiconductor light-emitting device; and

FIG. 9 is a plan view illustrating another example of the phase modulation layer.

### DETAILED DESCRIPTION

Hereinafter, a preferred embodiment of a semiconductor light-emitting device according to one aspect of the present disclosure will be described in detail with reference to the drawings.

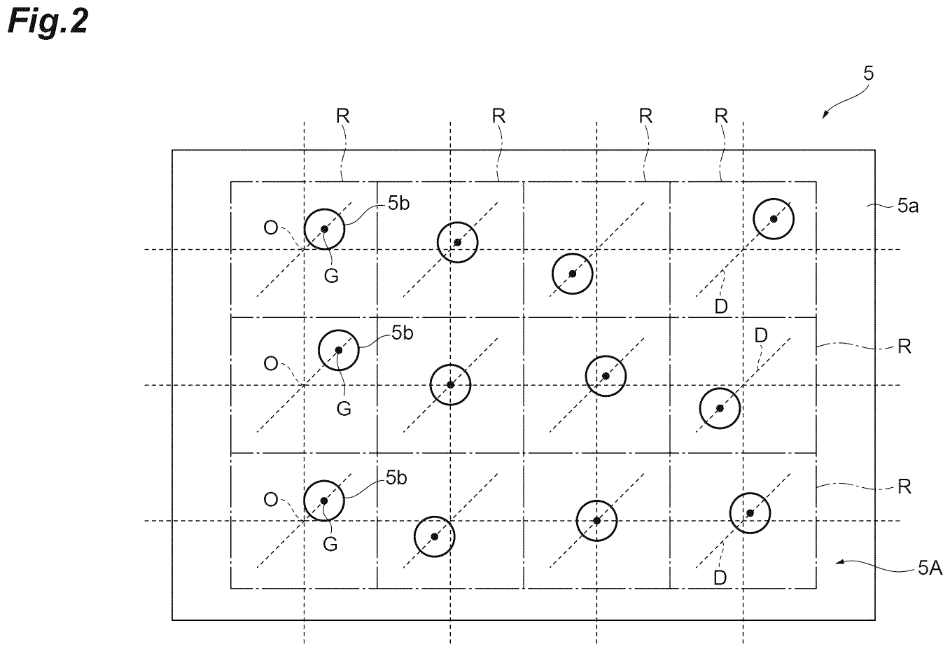

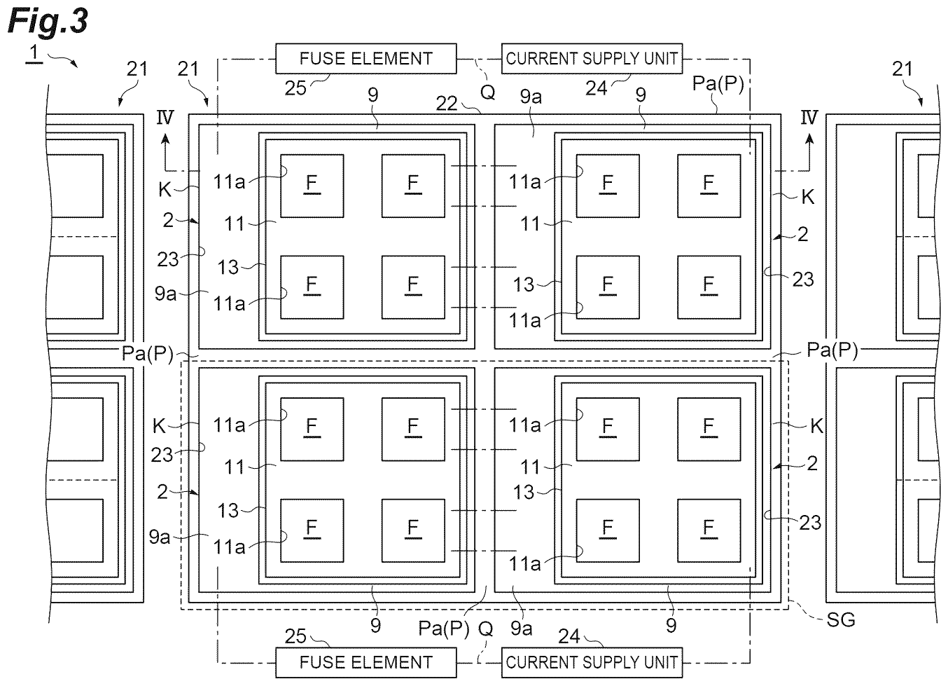

A semiconductor light-emitting device 1 according to the present embodiment (see FIGS. 2 and 3) is a device including a light-emitting element referred to as a so-called photonic crystal surface emitting laser (PCSEL). In the present embodiment, the semiconductor light-emitting device 1 is an iPMSEL (integrable phase modulating surface emitting lasers) capable of outputting a two-dimensional beam pattern. The semiconductor light-emitting device 1 includes a plurality of unit light-emitting elements 2. Each of the unit light-emitting elements 2 outputs a phase-controlled plane wave as laser light L in a direction intersecting a thickness direction of the unit light-emitting element 2 to form an optical image of any shape.

### Configuration of Unit Light-Emitting Element

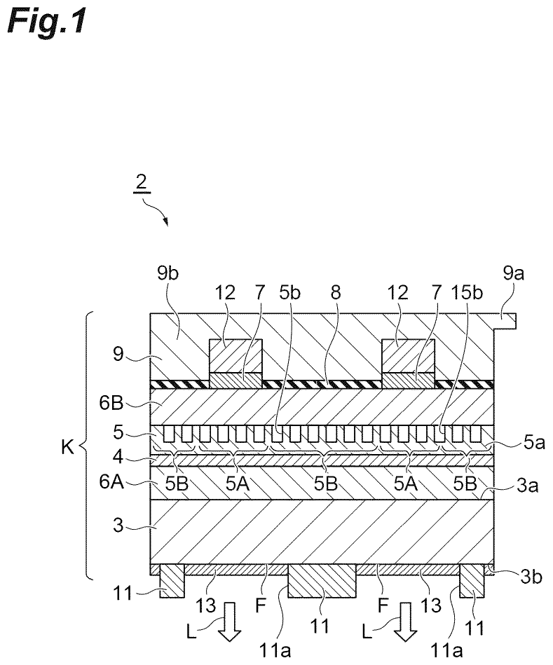

First, the unit light-emitting element 2 constituting the semiconductor light-emitting device 1 will be described. FIG. 1 is a schematic cross-sectional view illustrating a configuration of a unit light-emitting element. As illustrated in FIG. 1, the unit light-emitting element 2 includes a stacked structure K including a substrate 3, an active layer 4, and a phase modulation layer 5. The substrate 3 is, for example, a semiconductor substrate. The substrate 3 includes a compound semiconductor such as a GaAs-based semiconductor, an InP-based semiconductor, or a nitride-based semiconductor. The substrate 3 has a first surface 3a and a second surface 3b opposing each other. The facing direction of the first surface 3a and the second surface 3b is along a stacking direction of each layer in the stacked structure K.

In the present embodiment, a cladding layer 6A, the active layer 4, the phase modulation layer 5, and a cladding layer 6B are stacked in this order on the first surface 3a of the substrate 3. In addition, a contact layer 7, an insulating layer 8, and an outermost layer 9 are stacked on the cladding layer 6B. In the example of FIG. 1, the cladding layer 6A is a cladding layer having an n-type conductivity, and the cladding layer 6B is a cladding layer having a p-type conductivity. The active layer 4 and the phase modulation layer 5 are sandwiched between the cladding layer 6A and the cladding layer 6B.

In the example of FIG. 1, the phase modulation layer 5 is disposed between the active layer 4 and the cladding layer 6B, but the phase modulation layer 5 may be disposed between the cladding layer 6A and the active layer 4. A light guide layer may be disposed as necessary between the active layer 4 and the cladding layer 6A or between the active layer 4 and the cladding layer 6B. The light guide layer may include a carrier barrier layer for efficiently confining carriers in the active layer 4.

The cladding layer 6A, the active layer 4, the cladding layer 6B, and the contact layer 7 include a compound semiconductor such as a GaAs-based semiconductor, an InP-based semiconductor, or a nitride-based semiconductor. The active layer 4 has, for example, a multiple quantum well structure. The energy bandgap of the cladding layer 6A and the energy bandgap of the cladding layer 6B are larger than the energy bandgap of the active layer 4. Thickness directions of the cladding layer 6A, the active layer 4, the cladding layer 6B, and the contact layer 7 are along the stacking direction of the layers in the stacked structure K.

The phase modulation layer 5 is, for example, a photonic crystal layer whose refractive index periodically changes, and is optically coupled to the active layer 4. A thickness direction of the phase modulation layer 5 is along the stacking direction of each layer in the stacked structure K. In the example of FIG. 1, the phase modulation layer 5 includes a plurality of phase modulation regions 5A and a connection region 5B. The connection region 5B has, for example, a lattice shape in plan view. Each of the plurality of phase modulation regions 5A is arranged in an opening portion of the lattice-shaped connection region 5B. A planar shape of the phase modulation region 5A is, for example, a rectangular shape. The phase modulation regions 5A are arranged two-dimensionally in an in-plane direction of the phase modulation layer 5 and are optically coupled to each other.

The phase modulation regions 5A and the connection region 5B include a base region 5a having a first refractive index and a plurality of different refractive index regions 5b distributed two-dimensionally in the base region 5a with a second refractive index different from the first refractive index. The base region 5a includes a compound semiconductor such as a GaAs-based semiconductor, an InP-based semiconductor, or a nitride-based semiconductor. The different refractive index region 5b is constituted by, for example, a void. The different refractive index region 5b may be covered with a cap layer provided on the base region 5a. The cap layer may be, for example, a layer constituting a part of the phase modulation layer 5 using the same material as the base region 5a.

The plurality of different refractive index regions 5b is two-dimensionally distributed in each phase modulation region 5A. Here, the plurality of different refractive index regions 5b form a substantially periodic lattice structure. For example, in a case of M-point oscillation, when an equivalent refractive index of the mode is n and a lattice interval is a, a wavelength λ selected by each phase modulation region 5A is expressed by λ=(√2)×a×n. The wavelength λ is included in a light emission wavelength range of the active layer 4. Each phase modulation region 5A selects a band end wavelength near the wavelength λ from the light emission wavelength of the active layer 4 and outputs the selected band end wavelength to the outside. Light incident on each phase modulation region 5A from the active layer 4 forms a mode corresponding to the arrangement of the different refractive index regions 5b in each phase modulation region 5A, and is output as the laser light L from a light emission region F of the second surface 3b of the substrate 3 to the outside of the unit light-emitting element 2.

FIG. 2 is an enlarged plan view illustrating a part of the phase modulation region 5A. Although only one phase modulation region 5A is illustrated in FIG. 2, the other phase modulation regions 5A have the same configuration. In FIG. 2, a virtual square lattice is set for the phase modulation region 5A. Square unit constituent regions R each centered on a lattice point O of a square lattice are arranged two-dimensionally. The centroid position of each unit constituent region R coincides with the lattice point O of the virtual square lattice.

One different refractive index region 5b is provided in each unit constituent region R. The planar shape of the different refractive index region 5b is, for example, a circular shape. The lattice point O may be located in the different refractive index region 5b or may be located outside the different refractive index region 5b. Each of the different refractive index regions 5b has a centroid G. In the example of FIG. 2, the centroid G of the different refractive index region 5b is arranged on a straight line D set for each lattice point O. Each of the straight lines D is a straight line that passes through the lattice point O corresponding to each unit constituent region R and is inclined to each side of the square lattice. With such an arrangement of the different refractive index regions 5b, two of the four wave number vectors (for example, in-plane wave number vectors ±π/a and ±a) forming the standing wave of M points are phase-modulated, and the remaining two are not phase-modulated, so that a stable standing wave can be formed. Note that the centroid G of the different refractive index region 5b in the connection region 5B coincides with the lattice point O. For example, in a case where a virtual lattice point corresponding to the M-point oscillation is set, by providing the centroid G of the different refractive index region 5b at a position coincident with the lattice point O, it is possible to obtain a region in which a standing wave is formed in the in-plane direction and diffraction does not occur in the direction perpendicular to the plane.

Returning to FIG. 1, the stacked structure K of the unit light-emitting element 2 includes a first electrode 11 and second electrodes 12 having different polarities. The first electrode 11 is, for example, an n-side electrode located on the light emission region F side, and is provided on the second surface 3b of the substrate 3. The first electrode 11 is ohmically connected to the substrate 3. The first electrode 11 has a plurality of openings 11a. The opening 11a is disposed so as to have a one-to-one correspondence with the phase modulation region 5A. The opening 11a overlaps the corresponding phase modulation region when viewed from the stacking direction of each layer in the stacked structure K. A planar shape of the opening 11a is, for example, a rectangular shape. Each of the plurality of openings 11a constitutes the light emission region F. In the present embodiment, 2×2 light emission regions F are arranged in a lattice pattern on the second surface 3b side of the substrate 3.

An antireflection film 13 is provided in a portion of the second surface 3b of the substrate 3 exposed from the opening 11a. The antireflection film 13 is made of a single-layer film or a multi-layer film of a dielectric such as silicon nitride or silicon oxide. As the dielectric multilayer film, for example, a film obtained by stacking two or more kinds of dielectric layers selected from the dielectric layer group consisting of titanium oxide, silicon dioxide, silicon monoxide, niobium oxide, tantalum pentoxide, magnesium fluoride, titanium oxide, aluminum oxide, cerium oxide, indium oxide, and zirconium oxide can be used. The dielectric multilayer film is formed, for example, by stacking a plurality of films having an optical film thickness of λ/4 with respect to light having a wavelength λ.

The second electrodes 12 are, for example, p-side electrodes located on a side opposite to the light emission region F, and are provided on the contact layer 7. The second electrodes 12 are in ohmic contact with the contact layer 7. The second electrodes 12 overlap the corresponding phase modulation region when viewed from the stacking direction of each layer in the stacked structure K. The planar shape of the opening 11a is, for example, a rectangular shape. The second electrodes 12 are separated from each other. The second electrodes 12 are arranged so as to have a one-to-one correspondence with the phase modulation region 5A and the light emission region F. That is, in the present embodiment, 2×2 second electrodes 12 are arranged in a lattice pattern on the second surface 3b side of the substrate 3.

The contact layer 7 described above is removed by etching or the like except for a portion where the second electrode 12 is provided in order to narrow the current range. Thus, the contact layer 7 is divided into a plurality of parts so as to correspond to the second electrodes 12. The insulating layer 8 is provided on a portion of the surface of the cladding layer 6B where the contact layer 7 is removed. The insulating layer 8 is made of an inorganic insulating material such as silicon nitride or silicon oxide. Note that removal of the contact layer 7 in a portion where the second electrodes 12 are not provided is not necessarily performed. In this case, the insulating layer 8 is provided between the second electrodes 12 on the contact layer 7.

The outermost layer 9 is a thermoconductive outermost layer thermally coupled to the active layer 4 and the phase modulation layer 5. The outermost layer 9 constitutes an outermost portion on the side opposite to the light emission region F in the stacked structure K. The outermost layer 9 is an electroconductive outermost layer electrically connected to the second electrodes 12. The outermost layer 9 is formed by, for example, vapor deposition so as to fill irregularities on surface portions of the insulating layer 8 and the second electrodes 12. In the present embodiment, the outermost layer 9 is made of a material having high thermoconductivity and high electroconductivity such as gold, and has both a function as a thermoconductive outermost layer and a function as an electroconductive outermost layer. The outermost layer 9 is provided on the cladding layer 6B so as to cover the contact layer 7, the insulating layer 8, and the second electrodes 12. The outermost layer 9 includes an overhanging portion 9a overhanging in a direction intersecting the stacking direction in the stacked structure K and a main body portion 9b located on the cladding layer 6B.

The overhanging portion 9a is used for electrical connection between the unit light-emitting elements 2 (details will be described later). The overhanging portion 9a is made of, for example, indium solder. The main body portion 9b is made of, for example, gold. Note that the outermost layer 9 does not necessarily have both the function as the thermoconductive outermost layer and the function as the electroconductive outermost layer. For example, a layer having excellent thermoconductivity and electroconductivity may be provided on the cladding layer 6B so as to cover the contact layer 7, the insulating layer 8, and the second electrodes 12, and an outermost layer having only thermoconductivity may be provided on the layer. In this case, the outermost portion of the stacked structure K can be constituted by the layer having excellent thermoconductivity and electroconductivity and the thermoconductive outermost layer.

In the unit light-emitting element 2 having the above configuration, when a drive current is supplied between the first electrode 11 and the second electrodes 12, recombination of electrons and holes occurs at a portion immediately below the second electrodes 12 in the active layer 4, and light is output at the portion. Electrons and holes contributing to light emission and light output from the active layer 4 are efficiently confined between the cladding layers 6A and 6B.

The light output from the active layer 4 is incident on the phase modulation layer 5. In the phase modulation layer 5, the incident light resonates in the in-plane direction in the phase modulation region 5A, so that a mode corresponding to the arrangement of the plurality of different refractive index regions 5b is formed and becomes the laser light L. A part of the laser light L passes through the substrate 3 and is output to the outside from the opening 11a which is the light emission region F. The remainder of the laser light L is reflected by the second electrodes 12, passes through the substrate 3, and is output to the outside from the opening 11a which is the light emission region F.

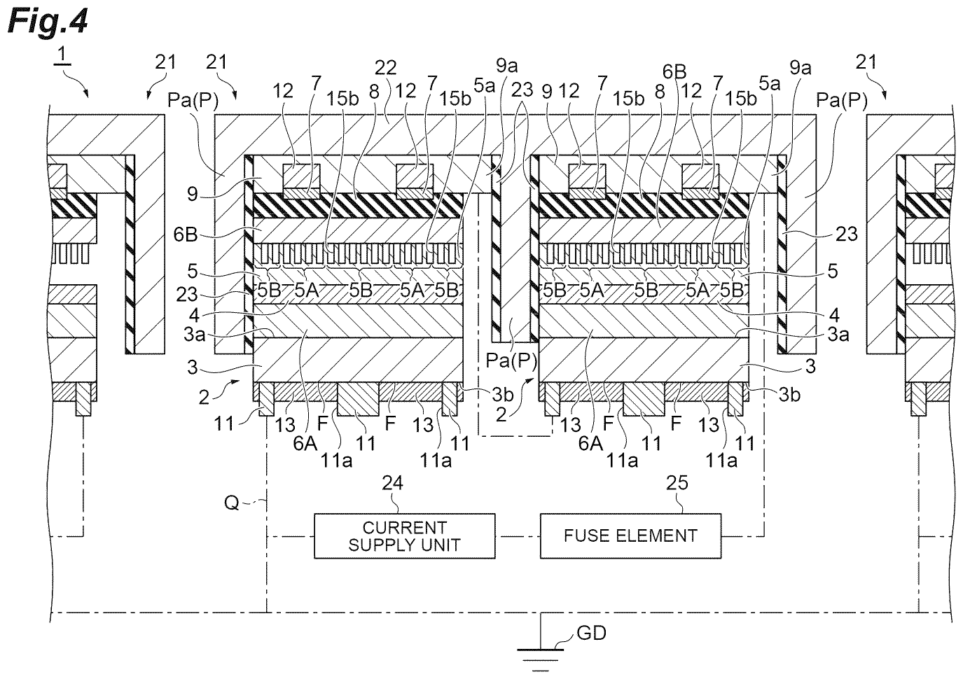

In the present embodiment, the second electrodes 12 are electrically connected to a current path Q (see FIGS. 3 and 4) to be described later via wiring. Each of the current paths Q electrically connected to each segment SG can freely change the magnitude of the drive current supplied to the segment SG. Therefore, on/off and intensity of the laser light L emitted from each light emission region F can be set independently for each light emission region F.

### Configuration of Semiconductor Light-Emitting Device

FIG. 3 is a schematic plan view illustrating a configuration of the semiconductor light-emitting device. Further, FIG. 4 is a cross-sectional view taken along line IV-IV in FIG. 3. As illustrated in FIGS. 3 and 4, in the semiconductor light-emitting device 1, the plurality of unit light-emitting elements 2 is two-dimensionally arranged in a state of being separated from each other, thereby forming a light-emitting element array 21. In the present embodiment, one light-emitting element array 21 is configured by arranging 2×2 unit light-emitting elements 2 in a lattice pattern. In the semiconductor light-emitting device 1, light-emitting element arrays 21 are further two-dimensionally arranged. In the examples of FIGS. 3 and 4, the light-emitting element arrays 21 are arranged in one direction, but in an actual semiconductor light-emitting device, n×m (n and m are integers) light-emitting element arrays 21 may be arranged in a lattice pattern.

Note that the unit light-emitting elements 2 arranged in the light-emitting element array 21 are not limited to 2×2 arrangement, and may be i×j (i and j are integers) arrangement. The number of unit light-emitting elements arrayed in the light-emitting element array 21 may be different for each light-emitting element array 21. In the semiconductor light-emitting device 1, the n×m light-emitting element arrays 21 need not be arranged, and a single light-emitting element array 21 may be used as the semiconductor light-emitting device 1.

The stacked structures K in the plurality of unit light-emitting elements 2 constituting the light-emitting element array 21 are independent of each other. That is, the substrate 3, the cladding layer 6A, the active layer 4, the phase modulation layer 5, the cladding layer 6B, the contact layer 7, the insulating layer 8, the outermost layer 9, the first electrode 11, the second electrodes 12, the antireflection film 13, and the light emission region F in the plurality of unit light-emitting elements 2 are separated from each other at a predetermined interval in the arrangement direction.

The light-emitting element array 21 includes a cooling unit 22 thermally coupled in common to the outermost layer 9 of each of the plurality of unit light-emitting elements 2. The cooling unit 22 is formed of, for example, a Peltier element. The cooling unit 22 may be constituted by a plate-like member or the like having a pipe for circulating a cooling medium therein. In the present embodiment, the cooling unit 22 includes a positioning portion P corresponding to each of the plurality of unit light-emitting elements 2 included in the light-emitting element array 21.

The positioning portion P includes, for example, a wall portion Pa extending in the stacking direction of the stacked structure K in the unit light-emitting element 2. In the examples of FIGS. 3 and 4, the wall portion Pa is formed in a lattice shape so as to partition 2×2 unit light-emitting elements 2 in a plan view of the light-emitting element array 21. The wall portion Pa is orthogonal to the main body portion (portion coupled to the outermost layer 9) of the cooling unit 22 and extends in the stacking direction of the stacked structure K at a height reaching the substrate 3. The wall portion Pa is formed, for example, by providing a recess in a main body portion of the cooling unit 22. In this case, the wall portion Pa is configured by the main body portion of the cooling unit 22.

An insulating film 23 is provided on a surface of the wall portion Pa on the stacked structure K side. The insulating film 23 is made of an inorganic insulating material such as silicon nitride or silicon oxide. In the present embodiment, the insulating film 23 is provided on the entire surface of the wall portion Pa on the stacked structure K side. The unit light-emitting elements 2 included in the light-emitting element array 21 are positioned on the cooling unit 22 by bringing one side surface of the stacked structure K (here, a side surface opposite to the direction in which the overhanging portion 9a of the outermost layer 9 overhangs) into contact with the wall portion Pa via the insulating film 23.

Note that, regarding the positioning of the plurality of unit light-emitting elements 2 included in the light-emitting element array 21, the stacked structure K of the plurality of unit light-emitting elements 2 may be collectively manufactured by a semiconductor film forming process. In this case, the outermost layer 9 may be stacked on each of the unit light-emitting elements 2, the cooling unit 22 common to the outermost layers 9 of the respective unit light-emitting elements 2 may be coupled, and then the stacked structure K of the unit light-emitting elements 2 may be separated by dry etching or wet etching. According to this method, it is possible to sufficiently secure the positional accuracy of the plurality of unit light-emitting elements 2 included in the light-emitting element array 21 without providing the wall portion Pa in the cooling unit 22.

The overhanging portion 9a of the outermost layer 9 is used for electrical connection between the plurality of unit light-emitting elements 2 included in the light-emitting element array 21. In the present embodiment, the current path Q is formed in units of a pair of unit light-emitting elements 2 adjacent to each other among the 2×2 unit light-emitting elements 2. The pair of unit light-emitting elements 2 adjacent to each other is electrically connected in series by connecting the overhanging portion 9a of one unit light-emitting element 2 to the first electrode 11 of the other unit light-emitting element 2.

In the present embodiment, the current path Q is formed for each of the pair of unit light-emitting elements 2 adjacent to each other. The current path Q for each of the pair of unit light-emitting elements 2 adjacent to each other is electrically connected to a common ground GD (see FIG. 4). Each current path Q includes a current supply unit 24 and a fuse element 25. The current supply unit 24 and the fuse element 25 are electrically connected in series between the first electrode 11 of one unit light-emitting element 2 and the overhanging portion 9a of the other unit light-emitting element 2 in each current path Q. Note that the “unit light-emitting elements 2 adjacent to each other” forming the current path Q is not limited to an aspect in which the pair of unit light-emitting elements 2 is adjacent to each other, and may include an aspect in which three or more unit light-emitting elements are adjacent to each other.

The current supply unit 24 is a circuit including, for example, a power supply, a voltage converter, and the like, and supplies a drive current to the pair of unit light-emitting elements 2 adjacent to each other via the first electrode 11 and the second electrodes 12. The fuse element 25 is a portion that stops energization to the unit light-emitting element 2 when an overcurrent occurs in the current path Q due to leakage or the like. The fuse element 25 may be, for example, a bonding wire configured to be disconnected when a predetermined overcurrent flows. Since the fuse element 25 is provided in each of the current paths Q for each pair of unit light-emitting elements 2 adjacent to each other, the pair of unit light-emitting elements 2 in which no defect has occurred can continue to emit the laser light L. The segment SG including the unit light-emitting element 2 in which the defect has occurred can be replaced during driving of the segment SG not including the unit light-emitting element 2 in which the defect has occurred.

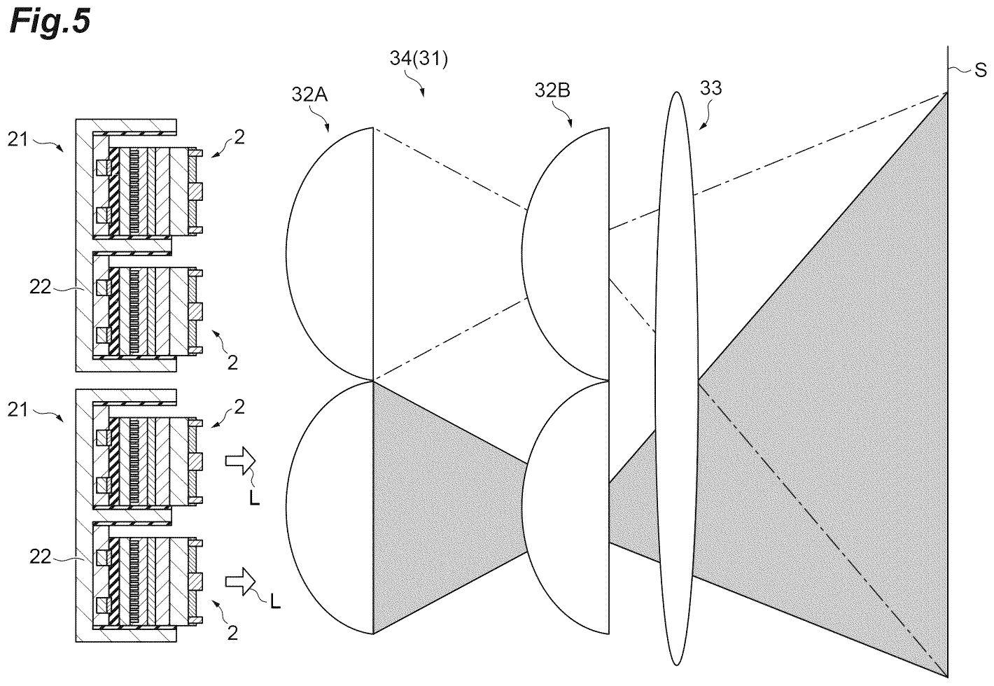

In the present embodiment, the semiconductor light-emitting device 1 further includes the illumination optical system 31 that uniformizes the laser light L emitted from the light emission region F. FIG. 5 is a schematic diagram illustrating an example of the illumination optical system. In the example of FIG. 5, the illumination optical system 31 includes a fly-eye integrator 34 including a pair of fly-eye lenses 32A and 32B and an illumination lens 33. The fly-eye integrator 34 is arranged so as to have a one-to-one correspondence with each of the plurality of unit light-emitting elements 2 included in the light-emitting element array 21, for example. The laser light L emitted from the plurality of light emission regions F of the unit light-emitting element 2 is spatially spread by the fly-eye integrator 34, and forms a light image at a designed irradiation position S with a uniform illuminance distribution.

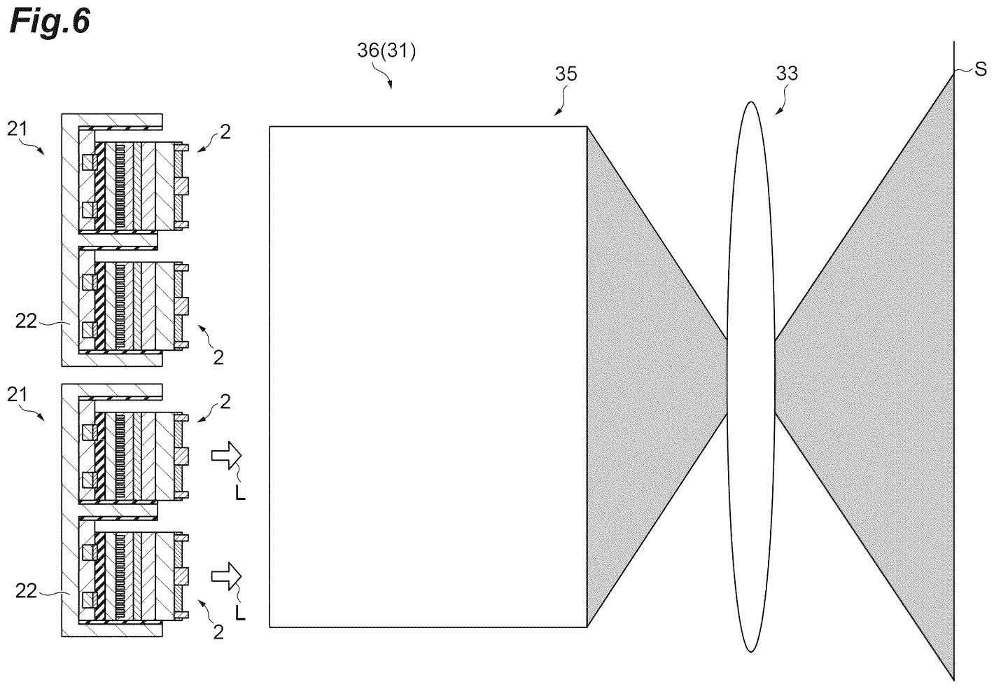

FIG. 6 is a schematic diagram illustrating an example of the illumination optical system. In the example of FIG. 6, the illumination optical system 31 includes a rod integrator 36 including a rod lens 35 and an illumination lens 33. The rod integrator 36 is arranged so as to have a one-to-one correspondence with each of the plurality of unit light-emitting elements 2 included in the light-emitting element array 21, for example. The laser light L emitted from the plurality of light emission regions F of the unit light-emitting element 2 is spatially spread by the rod integrator 36, and forms a light image in the same irradiation region at the designed irradiation position S with a uniform illuminance distribution.

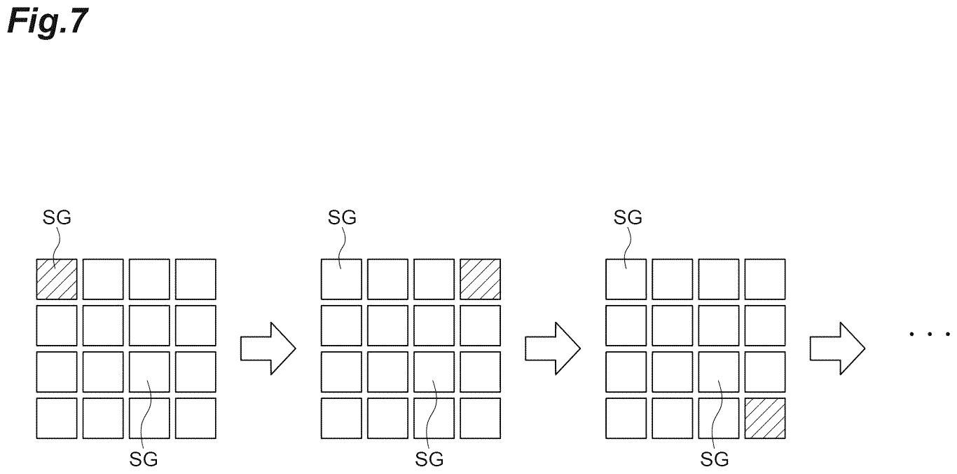

In the semiconductor light-emitting device 1 including the illumination optical system 31, it is preferable to sequentially turn on the segments SG from the viewpoint of improving an effective duty ratio in a case where the laser light L is used as signal light. In this case, for example, as illustrated in FIG. 7, the segments SG may be sequentially turned on one by one. When the segment SG is turned on, it is preferable to turn on the segment SG at a position not adjacent to the previously turned on segment SG. Thus, it is possible to suppress the influence of heat due to the lighting of the segment SG from reaching the next lighting segment SG.

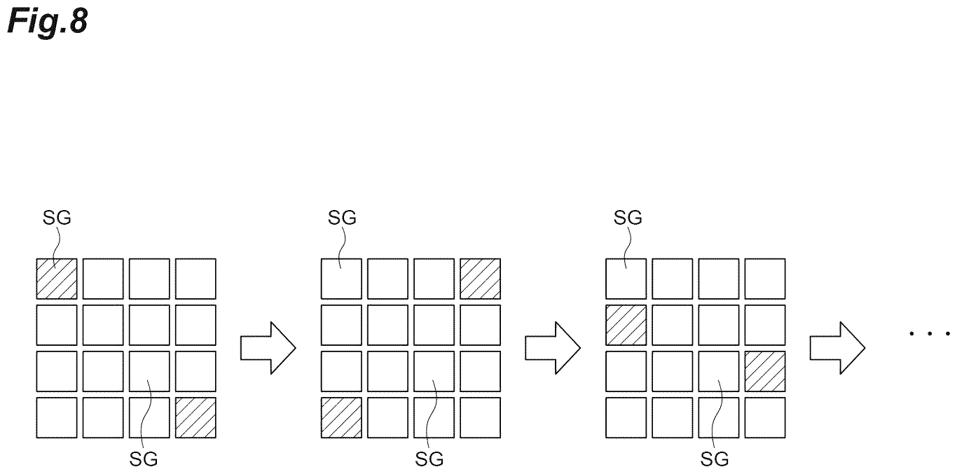

In addition, for example, as illustrated in FIG. 8, a plurality of (here, two) segments SG may be sequentially turned on. Also in this case, from the viewpoint of suppressing the influence of heat due to the lighting of the light emission region F from reaching the light emission region F to be turned on next, it is preferable to turn on the pair of light emission regions F at a position not adjacent to the pair of light emission regions F turned on immediately before.

### Operations and Effects

As described above, in the semiconductor light-emitting device 1, the stacked structures K of the unit light-emitting elements 2 having the plurality of light emission regions F is made independent of each other, and the plurality of unit light-emitting elements 2 is two-dimensionally arranged in a state of being isolated from each other to constitute the light-emitting element array 21. In the semiconductor light-emitting device 1, by including the plurality of light emission regions F in each unit light-emitting element 2 in which the stacked structures K are independent from each other, the element size of each unit light-emitting element 2 can be sufficiently secured, and the influence of a Fabry-Perot resonance mode between the end surfaces of the elements can be reduced. In addition, by two-dimensionally arranging the unit light-emitting elements 2 including the plurality of light emission regions F, it is possible to extract the laser light L from each light emission region F while eliminating an influence such as warpage of the substrate 3 due to heat generation during driving and a problem of mode competition. Therefore, in the semiconductor light-emitting device 1, the laser light L having desired characteristics can be extracted with high output.

Note that, specifically, when the element size of the unit light-emitting element 2 is about 500 μm×500 μm or more, the influence of the Fabry-Perot resonance mode can be effectively reduced. In addition, when the element size of the unit light-emitting element 2 is about 20 mm×20 mm or less, warpage of the substrate can be effectively suppressed. In this case, the size of the light emission region F is preferably about 50 μm×50 μm or more and about 500 μm×500 μm or less.

In the present embodiment, the unit light-emitting element 2 has a thermoconductive outermost layer thermally coupled to the active layer 4 and the phase modulation layer 5. In this case, heat during driving in the unit light-emitting element 2 can be efficiently released to the outside through the thermoconductive outermost layer. Thus, the output of the laser light L is stabilized.

In the present embodiment, the semiconductor light-emitting device 1 includes the cooling unit 22 thermally coupled in common to the thermoconductive outermost layer of each of the plurality of unit light-emitting elements 2. Thus, even when a large number of unit light-emitting elements 2 are two-dimensionally arranged, each unit light-emitting element 2 can be efficiently cooled. In addition, by making the cooling unit 22 common to the plurality of unit light-emitting elements 2, it is possible to avoid complication of the configuration of the light-emitting element array 21.

In the present embodiment, the cooling unit 22 includes the positioning portion P corresponding to each of the plurality of unit light-emitting elements 2. Thus, it is possible to improve the positional accuracy of each unit light-emitting element 2 when a large number of unit light-emitting elements 2 are two-dimensionally arranged. In the present embodiment, the positioning portion P is a wall portion Pa extending in the stacking direction of the stacked structure K, and an insulating film 23 is provided on a surface of the wall portion Pa on the side of the stacked structure K. With such a configuration, the unit light-emitting elements 2 can be easily positioned by abutting the stacked structure K against the wall portion Pa. In addition, by providing the insulating film 23 on the surface of the wall portion Pa on the stacked structure K side, occurrence of a short circuit due to the wall portion Pa can be prevented.

In the present embodiment, the unit light-emitting elements 2 each include an electroconductive outermost layer electrically connected to the second electrodes 12. In this case, the unit light-emitting elements 2 can be easily electrically connected to each other via the electroconductive outermost layer. In the present embodiment, the electroconductive outermost layer includes the overhanging portion 9a overhanging in a direction intersecting the stacking direction in the stacked structure K. By providing the overhanging portion 9a in the electroconductive outermost layer, it is easy to electrically connect the unit light-emitting elements 2 adjacent to each other.

In the present embodiment, the unit light-emitting elements 2 adjacent to each other are electrically connected in series by connecting the overhanging portion 9a of one unit light-emitting element 2 to the first electrode 11 of the other unit light-emitting element 2. According to such a configuration, even when a large number of unit light-emitting elements 2 are two-dimensionally arranged, the wiring can be simplified.

In the present embodiment, a current path Q including the current supply unit 24 and the fuse element 25 is formed for each pair of the unit light-emitting elements 2 adjacent to each other. According to such a configuration, when the unit light-emitting elements 2 adjacent to each other are sectionalized as one segment SG, the current supply unit 24 is provided for each segment SG, so that the variation in the output of the laser light L between the segments SG can be suppressed. In addition, since the fuse element 25 is provided for each segment SG, even when a failure occurs in one segment SG, it is possible to continue the output of the laser light L from another segment SG.

In the present embodiment, the current path Q for each pair of the unit light-emitting elements 2 adjacent to each other is electrically connected to the common ground GD. According to such a configuration, even when a large number of unit light-emitting elements 2 are two-dimensionally arranged, the wiring can be simplified.

In the present embodiment, the semiconductor light-emitting device 1 further includes the illumination optical system 31 that uniformizes the laser light L emitted from the segment SG. Thus, even when the laser light L is emitted from any of the plurality of segments SG, the same irradiation region at the designed irradiation position S can be irradiated with the laser light L. Therefore, the output of the semiconductor light-emitting device 1 can be further increased, and the degree of freedom in driving the device can be increased.

### Modifications

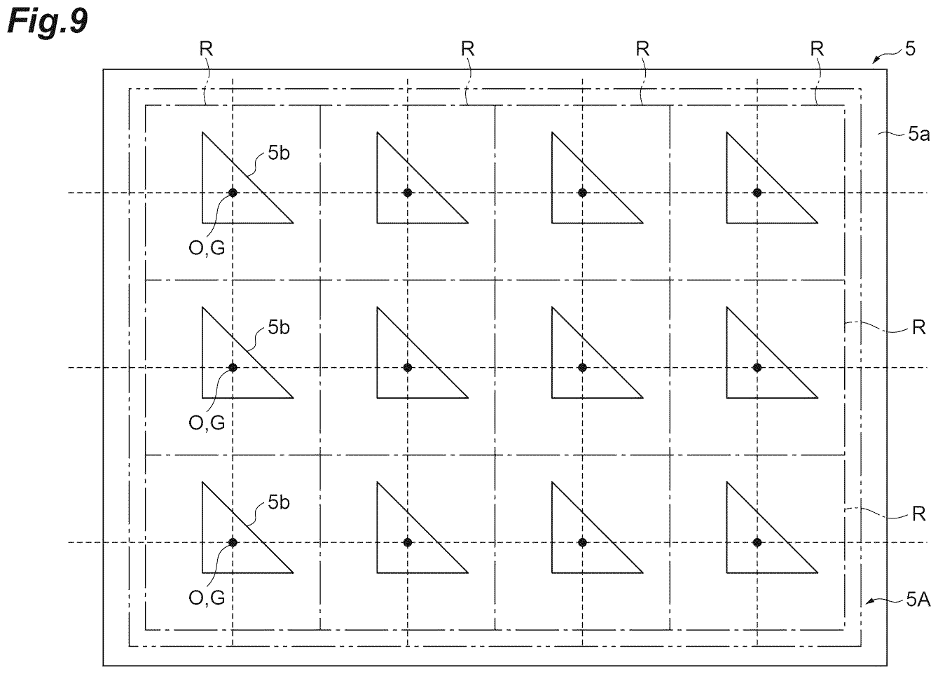

The present disclosure is not limited to the above embodiment. For example, in the above embodiment, iPMSEL is exemplified as an example of PCSEL, but the present disclosure is also applicable to normal PCSEL in which phase distribution control of light in an in-plane direction is not performed. In the case of the normal PCSEL, as illustrated in FIG. 9, in the phase modulation region 5A, the centroid G of the different refractive index region 5b is located so as to overlap with, for example, the virtual lattice point O corresponding to the Γ-point oscillation.

In the example of FIG. 8, a planar shape of the different refractive index region 5b is a right-angled isosceles triangle. The planar shape of the different refractive index region 5b can adopt various modes such as a perfect circular shape, an elliptical shape, a rectangular shape, and a polygonal shape, including the case of the iPMSEL. The shape of the virtual lattice is not limited to the square lattice including the case of the iPMSEL, and various modes such as a rectangular lattice, a triangular lattice, a face-centered rectangular lattice, and a honeycomb lattice can be adopted.

The lattice constant of the photonic crystal layer (phase modulation layer 5) may be different for each unit light-emitting element 2. In this case, in the active layer 4 produced by epitaxial growth or the like, the influence of the wavelength variation of light generated in the active layer 4 can be reduced among the unit light-emitting elements 2. Each of the plurality of light-emitting element arrays 21 included in the semiconductor light-emitting device 1 may be provided with an electrode pad for probe inspection. In this case, an energization test can be easily performed on each of the light-emitting element arrays 21. In addition, a mechanism that blows dry nitrogen toward the plurality of light-emitting element arrays 21 included in the semiconductor light-emitting device 1 may be provided.

The semiconductor light-emitting device 1 may include a holding substrate that holds the plurality of light-emitting element arrays 21 arranged two-dimensionally. In this case, an airtight package having the holding substrate as a part of the wall portion may be formed. In the airtight package, a gap between the holding substrate and the semiconductor light-emitting device may be sealed with resin. A cooling part that is in close contact with the holding substrate may be provided inside the airtight package. Examples of the cooling part in this case include a Peltier element and a cooling pipe through which a cooling medium such as water flows.

In the above embodiment, the current path Q is formed in units of a pair of unit light-emitting elements 2 adjacent to each other among the 2×2 unit light-emitting elements 2, but the formation mode of the current path Q in the light-emitting element array 21 is not limited thereto. For example, the current path Q may be formed in each of the plurality of unit light-emitting elements 2 included in the light-emitting element array 21, or the current path Q may be formed by electrically connecting all of the plurality of unit light-emitting elements 2 included in the light-emitting element array 21 in series.

What is claimed is:

1. A semiconductor light-emitting device comprising a plurality of unit light-emitting elements, wherein
the unit light-emitting elements each include
a stacked structure including:
a substrate;
an active layer configured to generate light by supplying a drive current;
a phase modulation layer including a base region having a first refractive index and a plurality of different refractive index regions two-dimensionally distributed in the base region with a second refractive index different from the first refractive index;
a plurality of light emission regions configured to emit laser light generated by mode formation of the light incident on the phase modulation layer from the active layer to outside; and
a first electrode on a side of the light emission regions and a second electrode on a side opposite to the light emission regions, the first electrode and the second electrode having polarities different from each other,
the stacked structures in the plurality of unit light-emitting elements are independent from each other, and
the plurality of unit light-emitting elements is two-dimensionally arranged in a state of being separated from each other to constitute a light-emitting element array.

2. The semiconductor light-emitting device according to claim 1, wherein the unit light-emitting elements each include a thermoconductive outermost layer thermally coupled to the active layer and the phase modulation layer.

3. The semiconductor light-emitting device according to claim 2, further comprising a cooling unit thermally coupled in common to the thermoconductive outermost layer of each of the plurality of unit light-emitting elements.

4. The semiconductor light-emitting device according to claim 3, wherein the cooling unit includes a positioning portion corresponding to each of the plurality of unit light-emitting elements.

5. The semiconductor light-emitting device according to claim 4, wherein
the positioning portion is a wall portion extending in a stacking direction of the stacked structure, and
an insulating film is provided on a surface of the wall portion on a side of the stacked structure.

6. The semiconductor light-emitting device according to claim 1, wherein the unit light-emitting elements each include an electroconductive outermost layer electrically connected to the second electrode.

7. The semiconductor light-emitting device according to claim 6, wherein the electroconductive outermost layer has an overhanging portion overhanging in a direction intersecting a stacking direction in the stacked structure.

8. The semiconductor light-emitting device according to claim 7, wherein the unit light-emitting elements adjacent to each other are electrically connected in series by connecting the overhanging portion of one of the unit light-emitting elements to the first electrode of another of the unit light-emitting elements.

9. The semiconductor light-emitting device according to claim 8, wherein a current path including a current supply unit and a fuse element is formed for each of the unit light-emitting elements adjacent to each other.

10. The semiconductor light-emitting device according to claim 9, wherein the current path for each of the unit light-emitting elements adjacent to each other is electrically connected to a common ground.

11. The semiconductor light-emitting device according to claim 1, further comprising an illumination optical system configured to uniformize the laser light emitted from the light emission region.
